(19) United States
(12) Patent Application Publication
(10) Pub. No.: US 2003/0197242 A1
(43) Pub. Date: Oct. 23, 2003

(54) Structure and fabrication method of electrostatic discharge protection circuit

(75) Inventors: Shiao-Shien Chen, Chung-Li (TW); Tsun-Lai Hsu, Hsinchu Hsien (TW); Tien-Hao Tang, Taipei Hsien (TW); Hua-Chou Tseng, Hsinchu (TW)

Correspondence Address: WU & CHUENG, LLP, SUITE 710, 7700 IRVINE CENTER DRIVE, IRVINE, CA, 92618-3043, US

(73) Assignee: UNITED MICROELECTRONICS CORP.

(21) Appl. No.: 10/259,887

(22) Filed: Sep. 30, 2002

Related U.S. Application Data
(62) Division of application No. 10/134,415, filed on Apr. 29, 2002, now abandoned.

(30) Foreign Application Priority Data
Apr. 22, 2002 (TW) 91108180

(51) Int. Cl. H01L 29/00

(52) U.S. Cl. 257/509

(57) ABSTRACT

A structure of an electrostatic discharge protection circuit, using a deep trench structure to replace the guard ring at a periphery of the electrostatic discharge protection circuit. Consequently, the device area is smaller compared to the device with the guard ring. Moreover, the device area is further reduced because the distance between the transistors of the electrostatic discharge protection circuit is shortened. At the same time, the functions of latch-up immunity and substrate noise immunity are more effective.

### CROSS-REFERENCE TO RELATED APPLICATION

This application claims the priority benefit of Taiwan application serial no. 91108180, filed Apr. 22, 2002.

### BACKGROUND OF THE INVENTION

1. Field of the Invention

The invention relates in general to a structure and a fabrication method of an electrostatic discharge protection circuit. More particularly, the invention relates to a structure and a fabrication method of an electrostatic discharge protection circuit using a deep trench to replace the guard ring, such that the device area is reduced, and latch-up immunity and substrate noise immunity are achieved.

2. Description of the Related Art

Electrostatic discharge (ESD) is a phenomenon where electrostatic energy moves from nonconductors, and it damages integrated circuits (IC). For example, hundreds or thousands of electrostatic volts are carried when a human body walks on a carpet under a high relative humidity. When the relative humidity is low, more than ten thousand volts carried by the human body can be measured. The machine for packaging integrated circuits or the equipment for testing integrated circuits can also generate hundreds to thousands of volts of electrostatic discharge due to weather or humidity factors. When contacting with a chip, the charge carrier (human body, machine, or equipment) discharges to the chip causing failure of the integrated circuit on the chip.

To prevent damaging the integrated circuit on the chip, various electrostatic discharge preventing methods have been developed. The most common conventional method is to employ hardware to prevent electrostatic discharge. That is, an on-chip electrostatic discharge protection circuit is formed between the internal circuit and each pad to protect the internal circuit.

FIG. 1 shows the structure of a conventional electrostatic discharge protection device. In FIG. 1, a P-type substrate 100 is isolated by a shallow trench isolation layer 140 to form a PMOS region 150 and NMOS region 160, wherein an N-well 102 is formed in the P-type substrate 100 of the PMOS region 150. A PMOS transistor 106 and a N+ pick up region 116 are then formed in the N-well 102.

The above PMOS transistor 106 comprises a gate 108, a source 110, and a drain 112. In the N-well 102, a shallow trench isolation layer 114 is formed to isolate the N+ pick up region 116 and the PMOS transistor 106.

Further, a guard ring 120 is formed at a periphery of the N+ pick up region 116. For the PMOS transistor 106, the guard ring 120 includes a P+ doped region surrounding the N+ pick up region 116. The guard ring 120 is isolated from the N+ pick up region 116 by a shallow trench isolation layer 118.

A P well 104 is formed in the P-type substrate 100 of the NMOS region 160. An NMOS transistor 122 and a P+ pick up region 132 are then formed in the P well 104.

The above NMOS transistor 122 comprises a gate 124, a source 126, and a drain 128. In the P-well 104, a shallow trench isolation layer 130 is formed to isolate the P+ pick up region 132 and the NMOS transistor 122.

Further, a guard ring 136 is formed at a periphery of the P+ pick up region 132. For the NMOS transistor 122, the guard ring 136 includes an N+ doped region surrounding the NMOS transistor 122. The guard ring 136 is isolated from the P+ pick up region 132 by a shallow trench isolation layer 134.

In the structure as shown in FIG. 1, the guard rings are formed to prevent the latch-up phenomenon. However, the guard rings surrounding the PMOS transistor and the NMOS transistor occupy a significantly large area.

In addition to the formation of guard rings, in the I/O design, a distance X between the PMOS transistor and the NMOS transistor has to be maintained to effectively prevent occurrence of the latch-up phenomenon. Such a layout further wastes a lot of space.

### SUMMARY OF THE INVENTION

According to the above drawbacks of the conventional structure, the invention provides an electrostatic discharge protection structure and a fabrication method for fabricating the same. By replacing the guard ring with a deep trench structure, the area consumed by the guard ring is saved.

The invention further provides a structure and a fabrication method of an electrostatic discharge protection circuit that employs a deep trench structure to replace the guard ring, so that the space for isolating two neighboring transistors is reduced.

The structure and fabrication method of an electrostatic discharge protection circuit provided by the invention uses a deep trench structure to save the area and to prevent occurrence of latch-up effect at the same time.

The structure and fabrication method of an electrostatic discharge protection circuit provided by the invention uses a deep trench structure to save the area and to prevent occurrence of substrate noise at the same time.

The structure of an electrostatic discharge protection circuit provided by the invention includes a substrate, an N-well, a P-well, a PMOS transistor, an NMOS transistor, an N+ pick up region, a P+ pick up region, a first, a second, a third, and a fourth isolation layers, a deep trench isolation layer, and a buried layer. The N-well is formed in the substrate, and the PMOS transistor is formed in the N-well. The PMOS transistor comprises a gate, a source and a drain. The first isolation layer is formed in the N-well to isolate the N+ pick up region and the PMOS transistor. The second isolation layer is formed in the substrate to isolate the N+ pick up region and deep trench isolation layer. The P-well is formed in the substrate, and the NMOS transistor and a P+ pick up region is formed in the P-well. The NMOS transistor comprises a gate, a source and a drain. The third isolation layer is formed in a part of the substrate to isolate the P+ pick up region and the NMOS transistor. The fourth isolation layer is formed in the substrate to isolate the P+ pick up region and the deep trench isolation layer. The N-well and the P-well are isolated from each other by the deep trench isolation layer. The N+ buried layer is formed under the N-well and is connected thereto.

The fabrication method of an electrostatic discharge protection circuit provided by the invention comprises the following steps. A substrate having an N-well and a P-well is provided. A buried layer is formed at a junction between the N-well and the substrate. A plurality of deep trench isolation layers is formed in the substrate to isolate the P-well, the N-well and other devices. A PMOS gate and an NMOS gate are simultaneously formed on the N-well and the P-well, respectively. A PMOS source and a PMOS drain are formed in the N-well at two sides of the PMOS gate, while an N+ pick up region is formed in the N-well. An NMOS source and an NMOS drain are formed in the P-well at two sides of the NMOS gate, while a P+ pick up region is formed in the P-well.

The fabrication method of an electrostatic discharge protection circuit can be integrated into a bipolar CMOS transistor (BiCMOS) process. Therefore, at least the fabrication process of the electrostatic discharge protection circuit and the process for fabricating the deep trench isolation layer of the BiCMOS are performed simultaneously.

Accordingly, the present invention forms a deep trench structure to replace the guard ring. As the area of the deep trench is smaller than that of the guard ring, the device area is shrunk.

Further, by replacing the guard ring with the above deep trench structure, the distance between two transistors in the electrostatic discharge protection circuit is shortened, while a good protection effect is maintained, and the latch-up immunity and substrate noise immunity are still obtained.

In addition, while integrating the fabrication of the electrostatic discharge protection circuit provided by the invention with the BiCMOS process, the deep trench isolation layers of the electrostatic discharge protection circuit and the bipolar transistor can be formed using the same photomask. Therefore, the additional photomask (additional photolithography) is not required.

Both the foregoing general description and the following detailed description are exemplary and explanatory only and are not restrictive of the invention, as claimed.

### BRIEF DESCRIPTION OF THE DRAWINGS

FIG. 1 schematically shows the structure of a conventional electrostatic discharge protection circuit;

FIG. 2 schematically shows the structure of an electrostatic discharge protection circuit according to the invention; and

FIGS. 3A to 3F show an embodiment of integrating the fabrication processes of an electrostatic discharge protection circuit and a BiCMOS.

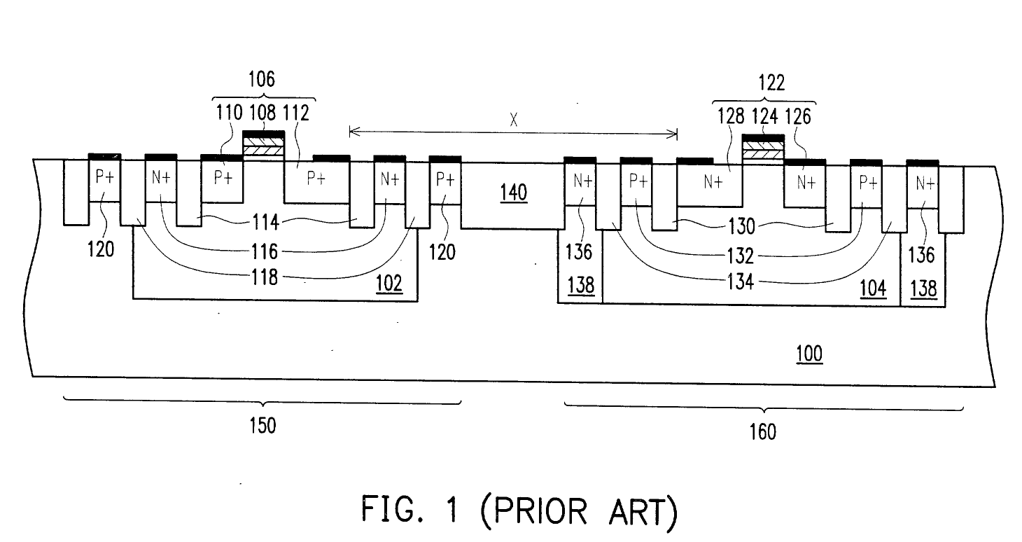

### DESCRIPTION OF THE PREFERRED EMBODIMENTS

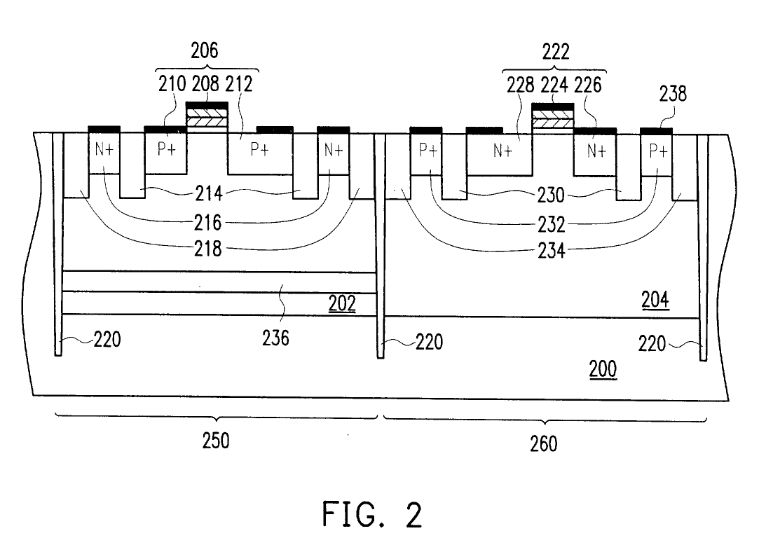

FIG. 2 shows the schematic drawing of a structure of an electrostatic discharge protection circuit in one embodiment of the invention.

In FIG. 2, an N-well 202 is formed on a P-type substrate 200 of the PMOS region 250. The depth of the N-well 202 is about 2 micron (μm), for example. A PMOS transistor 206 and a N+ pick up region 216 are formed in the N-well 202.

The above PMOS transistor 206 comprises a gate 208, a source 210, and a drain 212. In the N-well 202, the N+ pick up region 216, and the PMOS transistor 206 are isolated from each other by a shallow trench isolation layer 214. In one embodiment of the invention, the depth of the shallow trench isolation layer 214 is about 4000 angstroms, for example.

The invention uses a deep trench isolation layer 220 to replace the conventional guard ring. For the PMOS transistor 206 in this embodiment, the deep trench isolation layer 220 circumscribes the PMOS transistor 206, and it is isolated from the N+ pick up region 216 by the shallow trench isolation layer 218. The deep trench isolation layer 220 has a depth of about 5 micron, for example. As the depth of the deep trench isolation layer 220 is far greater than that of the shallow trench isolation layers 214 and 218, the PMOS transistor 206 and other devices can be isolated for protection thereby.

A P-well 204 is formed on a P-type substrate 200 of NMOS region 260. An NMOS transistor 222 and a P+ pick up region 232 are formed in the P-well 204.

The above NMOS transistor 222 comprises a gate 224, a source 226, and a drain 228. In the P-type substrate 200, the P+ pick up region 232 and NMOS transistor 222 are isolated from each other by the shallow trench isolation layer 230.

The same as the PMOS transistor 206, the deep trench isolation layer 220 at a periphery of the NMOS transistor 222 replaces the conventional guard ring. For the NMOS transistor 222 in this embodiment, the deep trench isolation trench layer 220 circumscribes the P+ pick up region 232. The deep trench isolation layer 220 has a depth of about 5 micron, for example.

As mentioned above, as the deep trench isolation layer 220 provides a good protection effect and effective latch-up and substrate noise immunity, the PMOS transistor and the NMOS transistor can be isolated with one deep trench isolation layer 220 to greatly reduce the distance X between these two transistors.

Further, a buried layer 236 is formed in the N-well 202 of the PMOS transistor 206. The dopant concentration of the buried layer 236 is higher than that of the N-well 202 to reduce the current gain, so as to enhance the latch-up prevention performance of the electrostatic discharge protection circuit.

In addition, self-aligned metal silicide 238 can be formed on the gates 208 and 224, the sources 210 and 226, the drains 212 and 228, the N+ pick up region 216 and the P+ pick up region 236 to reduce the resistance.

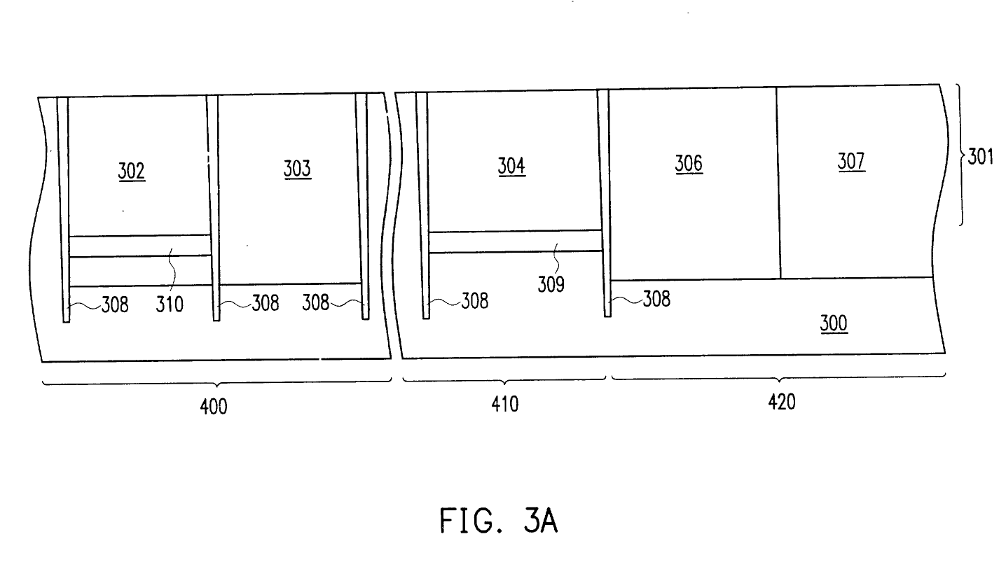

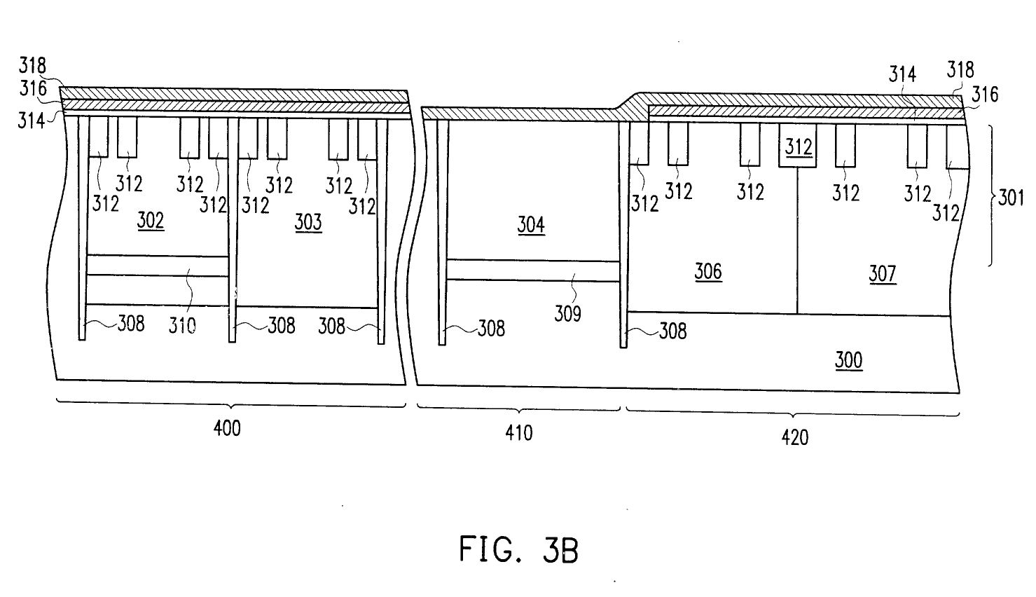

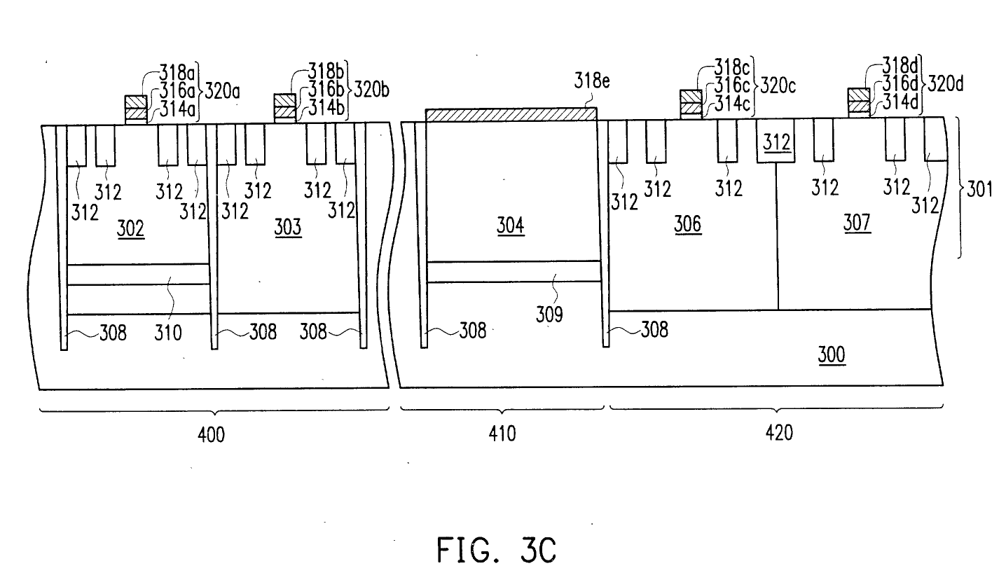

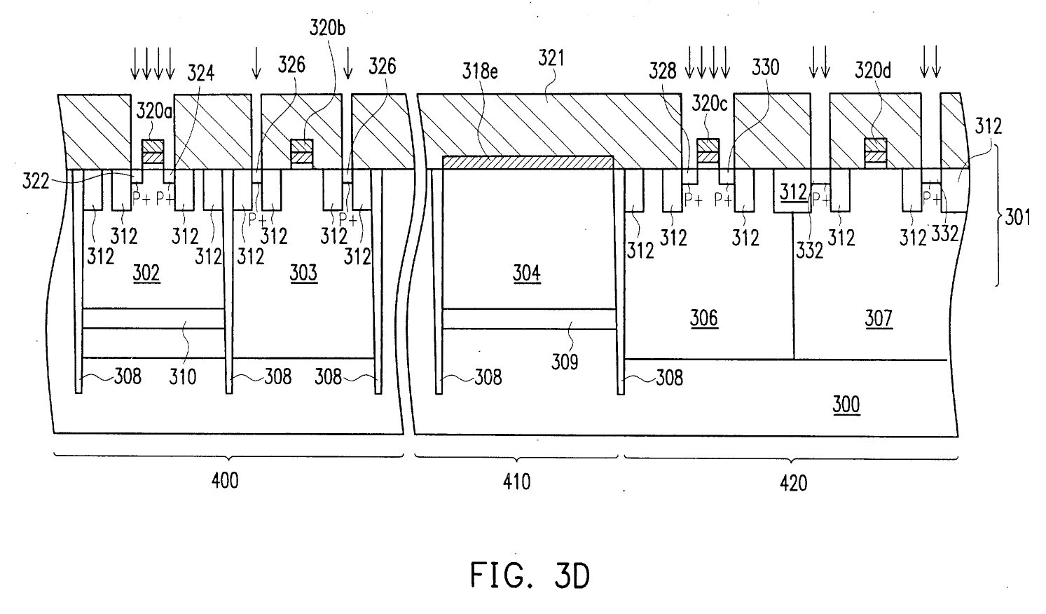

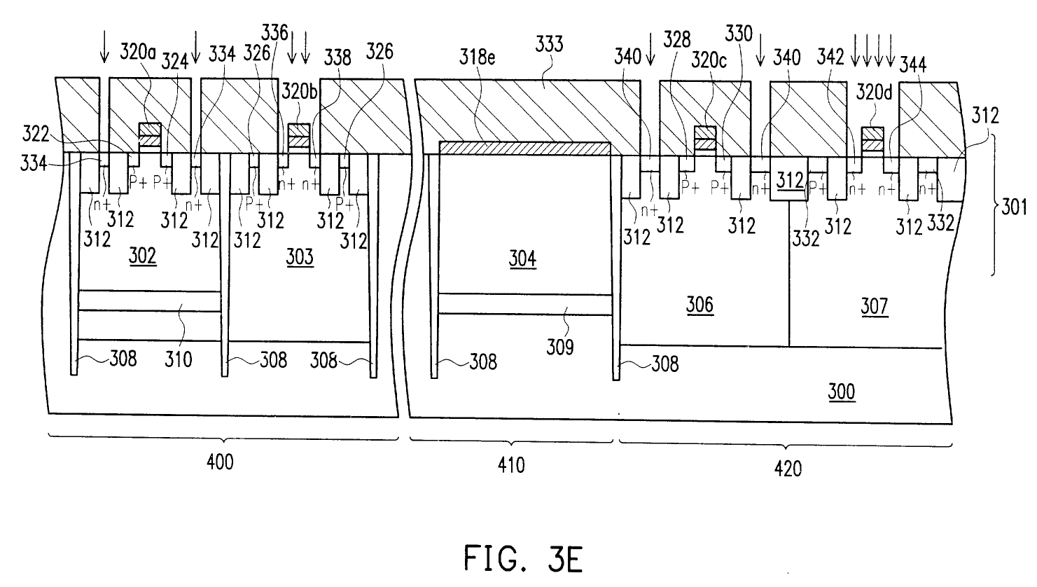

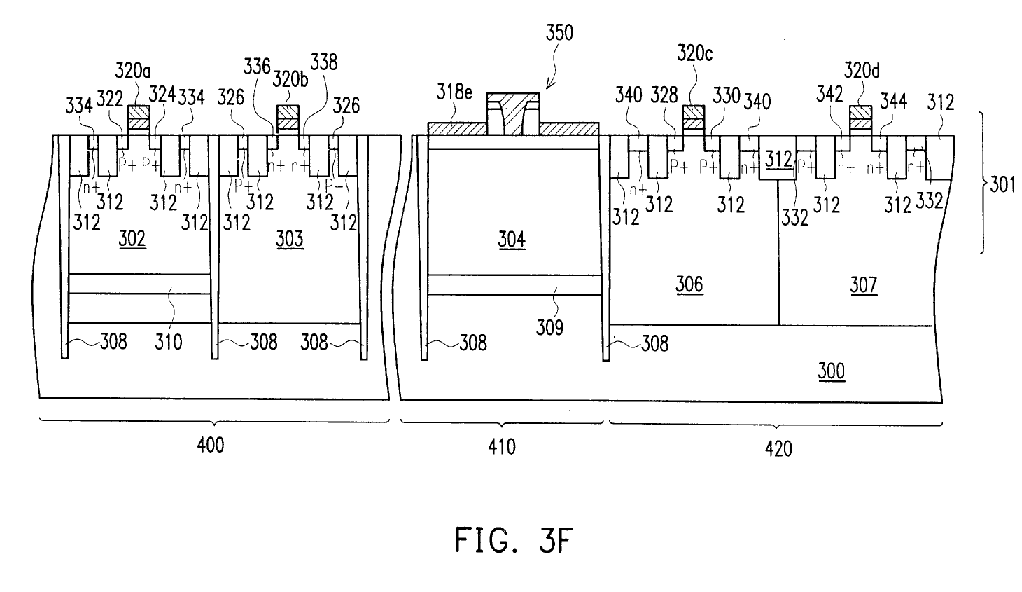

FIGS. 3A to 3F illustrate the fabrication process of integrating the electrostatic discharge protection circuit with the BiCMOS process.

In FIG. 3A, a substrate 300 is provided. An electrostatic discharge protection circuit (ESD) region 400, a bipolar region 410 and a CMOS region 420 are defined in the substrate 300. buried layers 310, 309 are formed on the substrate 300, and then an epitaxy layer 301 is formed on the buried layers 310, 309, wherein the buried layers 310, 309 are doped with N type ions. The epitaxy layer 301 is preferably doped. An N-well 302 and a P-well 303 are formed in the ESD region 400, an N-well 304 is already formed when growing the epitaxy layer 301 and is formed in the bipolar region 410, and an N-well 306 and a P-well 307 are formed in the CMOS region 420.

Further referring to FIG. 3A, a deep trench isolation layer 308 is formed between the epitaxy layer 301 and the substrate 300. The method for forming the deep trench isolation layer 308 includes forming a deep trench opening (not shown) between the epitaxy layer 301 and the substrate 300, followed by filling the deep trench opening with insulation material. In one embodiment of the invention, the material of the deep trench isolation layer 308 includes silicon oxide, while the depth thereof is about 5 micron, for example. The deep trench isolation layer 308 isolates the N-well 302, the P-well 303 of the ESD region 400 and other devices. The N-well 304 in the bipolar region 410 is also isolated by the deep trench isolation layer 308.

For the advanced BiCMOS process, the bipolar transistor is circumscribed with the deep trench isolation layer to prevent the substrate noise effect thereto. This is shown as the deep trench isolation layer 308 in FIG. 3A. Thus, the ESD region 400 is considered while designing the photomask, that is, the deep trench isolation layer 308 is formed in both the ESD region 400 and the bipolar region 410.

In FIG. 3B, a plurality of isolation layers 312 such as shallow trench isolation layers are formed in the epitaxy layer 301. The isolation layers 312 are formed to isolate the different doped regions formed in the same device subsequently. A gate dielectric layer 314 and a conductive layer 316 are then formed on the surfaces of the ESD region 400, the bipolar region 410 and the CMOS region 420. The gate dielectric layer 314 and the conductive layer 316 on the active region of the bipolar region 410 are then removed to expose the active region of the bipolar region 410. A conductive layer 318 is formed to cover the exposed surface in the bipolar region 410 and the conductive layer 316.

Referring to FIG. 3C, the conductive layer 318, the conductive layer 316, and the gate dielectric layer 314 are patterned. Conductive layers 318a, 318b, conductive layers 316a, 316b, and gate dielectric layers 314a, 314b are formed to construct a gate 320a and a gate 320b in the ESD region 400. A conductive layer 318e is formed in the bipolar region 410. Conductive layer 318c, 318d, conductive layers 316c, 316d and gate dielectric layers 314c and 314d are formed to construct gates 320c and 320d in the COMS region 420.

In FIG. 3D, a pattern mask layer 321 is formed on surfaces of the ESD region 400, the bipolar region 410, and the CMOS region 420. The mask layer 321 is used to perform a doping process, such that a source 322 and a drain 324 of an NMOS transistor and a P+ pick up region 326 adjacent to a PMOS transistor are formed in the ESD region 400. Meanwhile, a source 328, a drain 330 of a PMOS transistor, and a P+ pick up region 332 adjacent to an NMOS transistor, are formed in the CMOS region 420.

Referring to FIG. 3E, the mask layer 321 is removed, and a patterned mask layer 333 is formed on surfaces of the ESD region 400, the bipolar region 410 and the CMOS region 420. The mask layer 333 is used for performing a doping process to form a source 338, a drain 336, and an N+ pick up region 334 adjacent to a PMOS transistor, in the ESD region 400. Meanwhile, a source 344, a drain 342 of an NMOS transistor, and an N+ pick up region 340 adjacent to a PMOS transistor, are formed in the CMOS region 420.

For the electrostatic discharge protection circuit, the electrostatic discharge protection circuit and the CMOS structure is complete as shown in FIG. 3E. Referring to FIG. 3F, a bipolar transistor 350 is formed on the bipolar region 410. The subsequent processes are related to the bipolar transistor in the BICMOS process, which is prior art and is not further described.

For the BiCMOS process, the invention allows the deep trench isolation layer of the bipolar region 410 to be fabricated simultaneously. That is, the pattern of the ESD region 400 is considered while designing the photomask. Therefore, in the BiCMOS process, the deep trench isolation layer replacing the conventional guard ring is formed without increasing the amount of required photomask.

The above preferred embodiment integrates the process of electrostatic discharge protection circuit with the BiCMOS process to fabricate the deep trench isolation layer that replaces the conventional guard ring. However, the invention is not limited to the BiCMOS process. The invention can be applied to the process for forming the electrostatic discharge protection circuit only, or that for integrating the electrostatic discharge protection circuit with other processes.

The present invention forms a deep trench structure to replace the guard ring. As the area of the deep trench is smaller than that of the guard ring, the device area is shrunk.

Further, as the deep trench structure provides a good protection effect, the distance between two transistors in the electrostatic discharge protection circuit is shortened.

Moreover, as the deep trench structure provides a good protection effect while shortening the distance between two transistors, the latch-up immunity and substrate noise immunity are still obtained.

In addition, while integrating the fabrication of the electrostatic discharge protection circuit provided by the invention with the BiCMOS process, the deep trench isolation layers of the electrostatic discharge protection circuit and the bipolar transistor can be formed using the same photomask. Therefore, the additional photomask (additional photolithography) is not required.

Other embodiments of the invention will appear to those skilled in the art from consideration of the specification and practice of the invention disclosed herein. It is intended that the specification and examples are to be considered as exemplary only, with a true scope and spirit of the invention being indicated by the following claims.

What is claimed is:

1. A structure of an electrostatic discharge protection circuit, comprising:
a substrate;
a deep trench isolation layer, formed in the substrate;
an N well, formed in the substrate and using the deep trench isolation layer to isolate from other devices;
a P well, formed in the substrate and using the deep trench isolation layer to isolate from other devices;
a PMOS transistor, formed in the N well and comprising a PMOS gate, a PMOS drain and a PMOS source;
an N+ pick up region, formed in the N well;
a first isolation layer, in the N well to isolate the N+ pick up region, and the PMOS transistor;
a second isolation layer, in the N well to isolate the N+ pick up region and the deep trench isolation layer;
an NMOS transistor, formed in the P well and comprising an NMOS gate, an NMOS drain and an NMOS source;
a P+ pick up region, formed in the P well;
a third isolation layer, in the P well to isolate the P+ pick up region and the NMOS transistor;
a fourth isolation layer, in the P well to isolate the P+ pick up region and the deep trench isolation layer; and
a buried layer, formed in the N well.

2. The structure according to claim 1, wherein the substrate includes a P-type substrate.

3. The structure according to claim 1, wherein the deep trench isolation layer is about 5 micron thick.

4. The structure according to claim 3, wherein the deep trench isolation layer is thicker than the N well and the P well.

5. The structure according to claim 1, further comprising a self-aligned metal silicide layer formed on the gates, the sources, the drains, the N+ pick up region, and the P+ pick up region.

6. The structure according to claim 1, wherein the buried layer is doped with a same type of dopant as the N well.

7. The structure according to claim 1, wherein a dopant concentration of the buried layer is higher than that of the N well.

8. A method of fabricating an electrostatic discharge protection circuit, comprising:
providing a substrate in which an N well and a P well are formed;
forming a buried layer in the N well;
forming a deep trench isolation layer in the substrate, wherein the deep trench isolation layer isolates the P well, the N well and other devices;
simultaneously forming a PMOS gate on the N well and an NMOS gate on the P well;
forming a PMOS source and a PMOS drain in the N well at two sides of the PMOS gate, and an P+ pick up region in the P well; and
forming an NMOS source and an NMOS drain in the P well at two sides of the NMOS gate, and a N+ pick up region in the N well.

9. The method according to claim 8, further comprising forming an isolation layer between the N well and the P well to define the source, the drain and the pick up region to be formed after forming the deep trench isolation layer.

10. The method according to claim 8, further comprising forming the deep trench isolation layer thicker than the N well and the P well.

11. The method according to claim 8, further comprising a step of forming a buried layer doped with the same type as the N well.

12. The method according to claim 8, wherein the buried layer has a dopant concentration higher than that of the N-well.

13. A method of fabricating a BiCMOS device with an electrostatic discharge protection circuit, the method comprising:
providing a substrate in which the substrate is separated into an ESD region, a bipolar region and a CMOS region, wherein the ESD region has a first N well and a first P well, the CMOS region has a second N well and a second P well and the bipolar region has a third N well;
simultaneously forming a first buried layer at a horizontal junction between the first N well and the substrate, and a second buried layer in the third N well;
forming a deep trench isolation layer in the substrate, wherein the deep trench isolation layer isolates the first P well, the first N well and other devices, and also isolates the second P well, the second N well, the third N well and other devices;
simultaneously forming a first PMOS gate on the first N well and an first NMOS gate on the first P well, a second PMOS gate on the second N well and an second NMOS gate on the second P well, and a conductive layer on the third layer;
simultaneously forming a first PMOS source and a first PMOS drain in the first N well at two sides of the first PMOS gate, and a first N+ pick up region in the first N well, a second PMOS source and a second PMOS drain in the second N well at two sides of the second PMOS gate, and an second N+ pick up region in the second N well;
simultaneously forming a first NMOS source and a first NMOS drain in the first P well at two sides of the first NMOS gate, and a first P+ pick up region in the first N well, and a second NMOS source and a second NMOS drain in the second P well at two sides of the second NMOS gate, and a second P+ pick up region in the second N well; and
forming a bipolar transistor on the conductive layer.

14. The method according to claim 13, wherein the deep trench isolation layer of the BiCMOS process is formed at the same time when the deep trench isolation layer of the electrostatic discharge protection circuit is formed.

15. The method according to claim 13, further comprising forming an isolation layer between the first N well, the first P well, the second N well and the second P well to define the source, the drain and the pick up region to be formed after forming the deep trench isolation layer.

16. The method according to claim 13, wherein the first buried layer and the second buried layer are doped with N-type dopant.

17. The method according to claim 13, wherein the first buried layer and the second buried layer have a dopant concentration higher than that of the N well.

18. The method according to claim 13, wherein the deep trench isolation layer is thicker than the first N well, the first P well, the second N well and the second P well and the third N well.
